(19) United States
(12) Patent Application Publication
(10) Pub. No.: US 2025/0287652 A1
(43) Pub. Date: Sep. 11, 2025

(54) ISOLATION STRUCTURES IN SEMICONDUCTOR DEVICES

(71) Applicant: Taiwan Semiconductor Manufacturing Co., Ltd., Hsinchu (TW)

(72) Inventors: Kuan-Da HUANG, Hsinchu County (TW); Yu-Rung Hsu, Tainan City (TW); Li-Te Lin, Hsinchu (TW)

(73) Assignee: Taiwan Semiconductor Manufacturing Co., Ltd., Hsinchu (TW)

(21) Appl. No.: 18/599,797

(22) Filed: Mar. 8, 2024

(51) Int. Cl. H01L 29/06; H01L 21/8234; H01L 27/088; H01L 29/15; H01L 29/423; H01L 29/66; H01L 29/775; H01L 29/786

(52) U.S. Cl. CPC H10D 62/115; H10D 30/014; H10D 30/43; H10D 30/6735; H10D 30/6757; H10D 62/118; H10D 62/8171; H10D 84/0151; H10D 84/038; H10D 84/83

(57) ABSTRACT

A semiconductor device having an isolation structure and a method of fabricating the same are disclosed. The method includes forming first and second superlattice structures on a substrate, forming a dielectric oxide layer on the first and second superlattice structures, forming a polysilicon layer on the dielectric oxide layer, forming a first isolation opening above the first and second superlattice structures, forming a second isolation opening between the first and second superlattice structures, and depositing a dielectric layer in the first and second isolation openings to form an isolation structure. Forming the first isolation opening includes forming a first metal oxide layer on a first portion of the dielectric oxide exposed during forming of the first isolation opening. Forming the second isolation opening includes forming a second metal oxide layer on a second portion of the dielectric oxide layer exposed during forming of the second isolation opening.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs, fin field effect transistors (finFETs), and gate-all-around FETs (GAA FETs). Such scaling down has increased the complexity of semiconductor manufacturing processes.

### BRIEF DESCRIPTION OF THE DRAWINGS

Aspects of this disclosure are best understood from the following detailed description when read with the accompanying figures.

FIG. 1A illustrates an isometric view of a semiconductor device with an isolation structure, in accordance with some embodiments.

FIGS. 1B and 1C illustrate cross-sectional views of a semiconductor device with an isolation structure, in accordance with some embodiments.

FIG. 1D illustrates a top view of a semiconductor device with an isolation structure, in accordance with some embodiments.

FIG. 2 is a flow diagram of a method for fabricating a semiconductor device with an isolation structure, in accordance with some embodiments.

FIGS. 3-7, and 10-15 illustrate cross-sectional views of a semiconductor device with an isolation structure at various stages of its fabrication process, in accordance with some embodiments.

FIGS. 8 and 9 illustrate process mechanisms of fabrication processes of a semiconductor device with an isolation structure, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the process for forming a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phrasecology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5% of the value (e.g., ±1%, ±2%, ±3%, ±4%, ±5%, ±10%, ±10-15%, ±15˜20% of the value). These values are merely examples and are not intended to be limiting. The terms “about” and “substantially” can refer to a percentage of the values as interpreted by those skilled in relevant art(s) in light of the teachings herein.

The gate-all-around (GAA) transistor structures may be patterned by any suitable method. For example, the structures may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA transistor structure.

The present disclosure provides a semiconductor device and an example method for addressing challenges with forming poly-cut structures (also referred to as “isolation structures”) in a semiconductor device. The semiconductor device can include superlattice structures with nanostructured layers on fin bases. The nanostructured layers can include channel regions. As spacing between adjacent superlattice structures decreases with advance in semiconductor technology, defining and forming poly-cut structures between adjacent superlattice structures becomes challenging. Defining and forming poly-cut structures in a spacing less than about 25 nm between adjacent superlattice structures is challenging because extreme ultra-violet (EUV) lithography and etch processes used in the fabrication of the semiconductor device are unable to accommodate process variations. Furthermore, when the spacing is less than about 25 nm, the poly-cut opening (also referred to as an “isolation opening”) lands on top of the nanostructured layer of the superlattice structure, which can induce damage to the nanostructured layers during the formation of the poly-cut structures. The process of forming the poly-cut structures can be referred to as a “poly-cut process”.

To address these challenges, the present disclosure provides a method to protect the nanostructured layer of the superlattice structures using a protective oxide layer. The protective oxide layer can be formed on the superlattice structures prior to forming the poly-cut structures. Since, the protective oxide layer is thin, the poly-cut process can deteriorate the protective oxide layer, which can induce damage on uppermost nanostructured layers of the superlattice structures. The damage can be attributed to a high ion energy of ions of a poly-cut etchant of the poly-cut process, which can penetrate the thin protective oxide layer. Since the poly-cut etch process is an isotropic etch process, flat surfaces are more susceptible to ion damage than sidewall surfaces primarily because of the high energy with which the ions impinge on the flat surfaces. The damage can cause round top corners of the uppermost nanostructured layers of the superlattice structures. A difference in dimensions of the uppermost nanostructured layer compared to other nanostructured layers in the superlattice structure can cause the uppermost nanostructured layer to have current transfer characteristics different from the current transfer characteristics of the other nanostructured layers in the superlattice structure.

The present disclosure further provides an example method for protecting the protective oxide layer to prevent damage to the nanostructured layers (e.g., the uppermost nanostructured layer) of the superlattice structures. In some embodiments, the example method includes selectively depositing a protective metal oxide layer on surfaces of the protective oxide layer exposed during the poly-cut etch process. The protective metal oxide layer can be selectively formed on the protective oxide layer surfaces on sacrificial polysilicon structures. The protective metal oxide layer formation can also be selective to surfaces parallel to horizontal surfaces (e.g., top and bottom surfaces of protective oxide layer) over vertical surfaces (e.g., sidewall surfaces of protective oxide layer). This protective metal oxide layer can be formed during the poly-cut etch process and can be selectively deposited on horizontal surfaces of the protective oxide layer that get exposed during the poly-cut process.

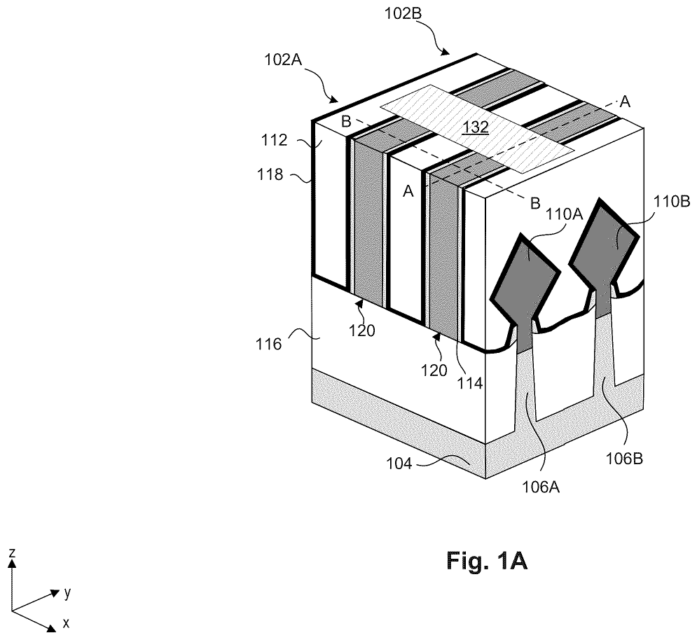

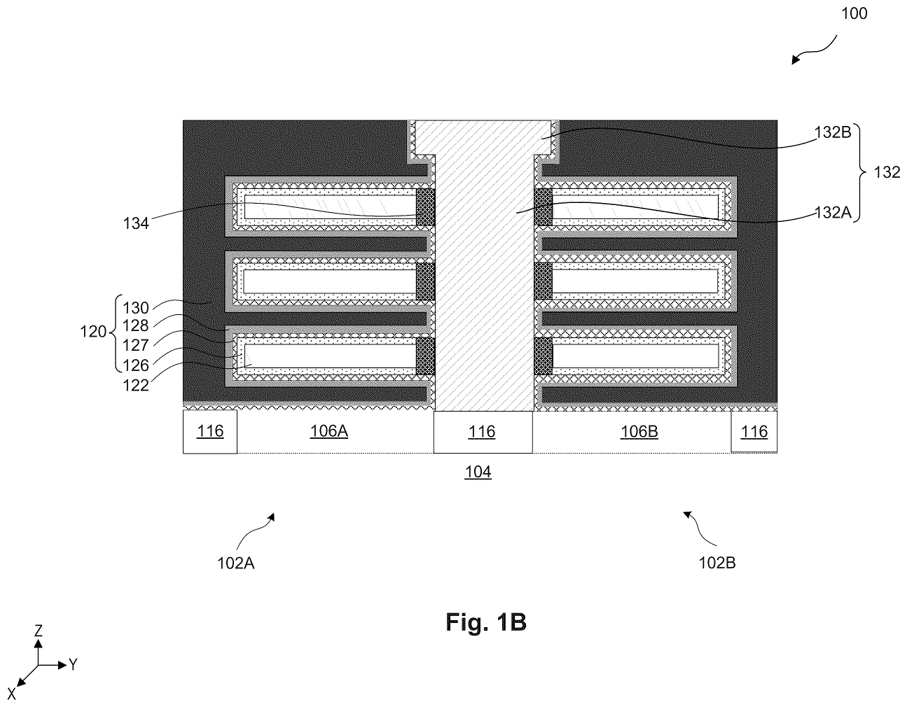

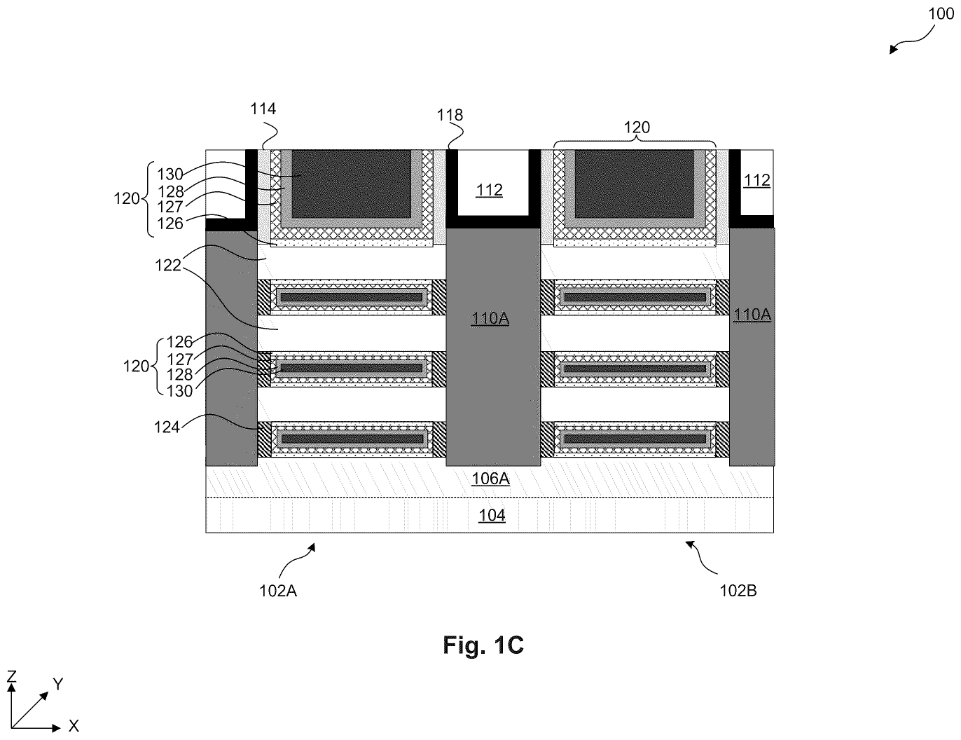

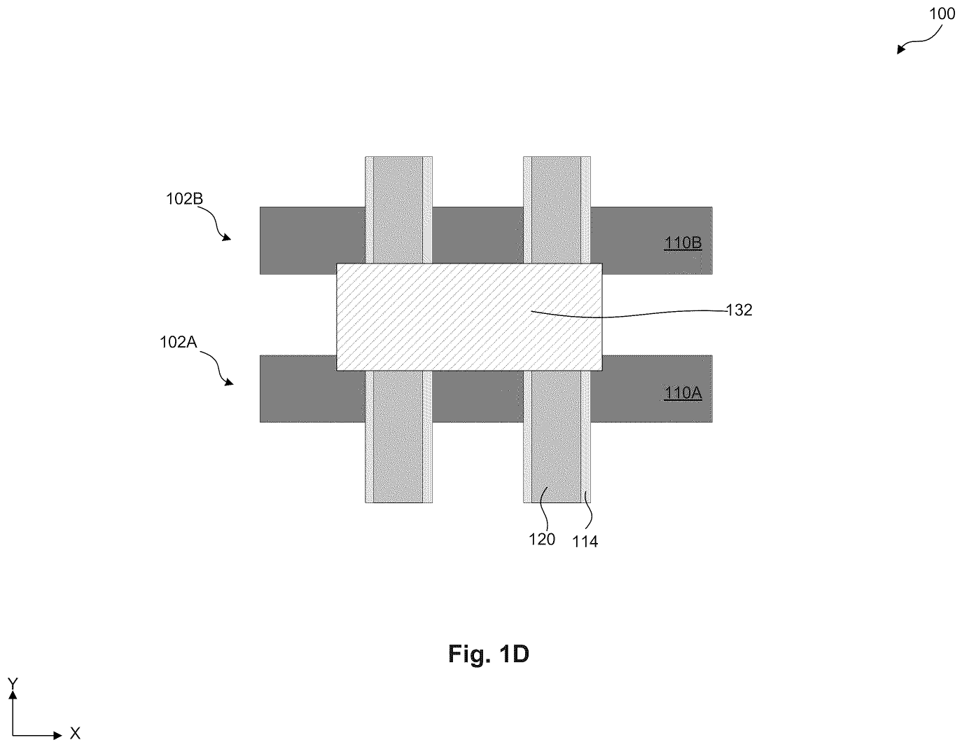

FIG. 1A illustrates an isometric view of a semiconductor device 100 with FETs 102A and 102B, according to some embodiments. Though semiconductor device 100 is shown to have two FETs 102A and 102B, semiconductor 100 can have any number of FETs. In some embodiments, FETs 102A and 102B can represent n-type FETs 102A and 102B (NFETs 102A and 102B) or p-type FETs 102A and 102B (PFETs 102A and 102B). The discussion of FETs 102A and 102B applies to both NFETs 102A and 102B, and PFETs 102A and 102B, unless mentioned otherwise. FIGS. 1B and 1C illustrate cross-sectional views of semiconductor device 100 along lines A-A and B-B of FIG. 1A, respectively. FIG. 1D shows a top view of semiconductor device 100 of FIG. 1A. FIGS. 1B and 1C illustrate cross-sectional views of semiconductor device 100 with additional structures that are not shown in FIG. 1A for simplicity. The discussion of elements of in FIGS. 1A-1D with the same annotations applies to each other, unless mentioned otherwise.

Referring to FIGS. 1A-1D, semiconductor device 100 can include (i) a substrate 104, (ii) fin bases 106A and 106B (also referred to as “sheet bases 106A and 106B” or “fin structures 106A and 106B”) disposed on substrate 104, (iii) nanostructured channel regions 122, (iv) gate structures 120 disposed on fin bases 106A and 106B, (v) gate spacers 114 disposed along sidewalls of gate structures 120, (vi) a poly-cut structure 132 (also referred to as an “isolation structure 132”) disposed between gate structures 120 on fin bases 106A and 106B, (vi) source/drain (S/D) regions 110A and 110B disposed on portions of fin bases 106A and 106B that are not covered by gate structures 120, (vii) shallow trench isolation (STI) regions 116, (viii) etch stop layer (ESL) 118 disposed directly on S/D regions 110A and 110B, (ix) interlayer dielectric (ILD) layers 112 disposed directly on ESLs 118, (x) protective oxide layers 134 along sidewalls of nanostructured channel regions 122, and (xi) inner spacers 124. The term “nanostructured” refers to a structure, layer, and/or region as having a horizontal dimension (e.g., along an X- and/or Y-axis) and/or a vertical dimension (e.g., along a Z-axis) less than about 100 nm, for example about 90 nm, about 50 nm, about 10 nm, or other values less than about 100 nm are within the scope of the disclosure. S/D regions 110A and 110B may refer to a source or a drain, individually or collectively dependent upon the context.

Semiconductor device 100 can be formed on substrate 104. There may be other FETs and/or structures (e.g., isolation structures) formed on substrate 104. Substrate 104 can be a semiconductor material, such as silicon (Si), germanium (Ge), silicon germanium (SiGe), a silicon-on-insulator (SOI) structure, other suitable semiconductor materials, and a combination thereof. Further, substrate 104 can be doped with p-type dopants (e.g., boron, indium, aluminum, or gallium) or n-type dopants (e.g., phosphorus or arsenic). In some embodiments, fin bases 106A and 106B can include a material similar to substrate 104 and can have elongated sides extending along an X-axis. In some embodiments, STI regions 116, ESLs 118, and ILD layers 112 can include an insulating material, such as silicon oxide (SiO₂), silicon nitride (SiN), silicon oxynitride (SiON), silicon oxycarbide (SiOC), silicon carbon nitride (SiCN), silicon oxycarbon nitride (SiOCN), silicon germanium oxide (SiGeOₓ), and other suitable insulating materials.

Referring to FIGS. 1B-1D, FETs 102A can include (i) a stack of nanostructured channel regions 122 disposed on fin base 106A and surrounded by gate structure 120, (ii) protective oxide layers 134 disposed on sidewalls of nanostructured channel regions 122 disposed on fin base 106A, and (iii) epitaxial S/D regions 110A disposed adjacent to the stack of nanostructured channel regions 122 disposed on fin base 106A. Similarly, FET 102B can include (i) a stack of nanostructured channel regions 122 disposed on fin base 106B and surrounded by gate structure 120, (ii) protective oxide layers 134 disposed on sidewalls of nanostructured channel regions 122 disposed on fin base 106B, and (iii) epitaxial S/D regions 110B disposed adjacent to the stack of nanostructured channel regions 122 disposed on fin base 106B. FIG. 1D does not show ILD layers 112 and ESLs 118 for simplicity.

Referring to FIGS. 1B and 1C, nanostructured channel regions 122 can include semiconductor materials similar to or different from substrate 104 and can include semiconductor material similar to or different from each other. In some embodiments, nanostructured channel regions 122 can include Si, silicon arsenic (SiAs), silicon phosphide (SiP), silicon carbide (SiC), silicon carbon phosphide (SiCP), SiGe, silicon germanium boron (SiGeB), germanium boron (GeB), silicon germanium stannum boron (SiGeSnB), a III-V semiconductor compound, or other suitable semiconductor materials. Though three nanostructured channel regions are shown in each stack, FETs 102A and 102B can include any number of nanostructured channel regions in each stack. Though rectangular cross-section of nanostructured channel regions 122 are shown, nanostructured channel regions 122 can have cross-sections of other geometric shapes (e.g., circular, elliptical, triangular, or polygonal). In some embodiments, nanostructured channel regions 122 can be in the form of nanosheets, nanowires, nanorods, nanotubes, or other suitable nanostructured shapes.

For NFETs 102A and 102B, S/D regions 110A and 110B can include an epitaxially-grown semiconductor material, such as Si, and n-type dopants, such as phosphorus and other suitable n-type dopants. For PFETs 102A and 102B, S/D regions 110A and 110B can include an epitaxially-grown semiconductor material, such as Si and SiGe, and p-type dopants, such as boron and other suitable p-type dopants.

Gate structure 120 can be multi-layered structures and can surround nanostructured channel regions 122, for which gate structure 120 can be referred to as “gate-all-around (GAA) structures” or “horizontal gate-all-around (HGAA) structures.” FET 102A can be referred to as “GAA FET 102A.” Gate portions of gate structure 120 surrounding nanostructured channel regions 122 can be electrically isolated from adjacent S/D region 110A by inner spacers 124, as shown in FIG. 1C. Gate portions of gate structure 120 disposed on the stacks of nanostructured channel regions 122 can be electrically isolated from adjacent S/D region 110A by gate spacers 114, as shown in FIG. 1C. Inner spacers 124 and gate spacers 114 can include an insulating material, such as SiO₂, SiN, SiCN, SiOCN, and other suitable insulating materials.

Gate structure 120 can include interfacial oxide (IL) layers 126, high-k (HK) gate dielectric layer 127 disposed on IL layer 126, work function metal (WFM) layers 128 disposed on HK gate dielectric layers 127, and gate metal fill layers 130 disposed on WFM layers 128. As used herein, the term “high-k (HK)” refers to a high dielectric constant. In the field of semiconductor device structures and manufacturing processes, HK refers to a dielectric constant that is greater than the dielectric constant of SiO₂ (e.g., greater than 3.9).

IL layers 126 can include silicon oxide SiO₂, silicon germanium oxide (SiGeOₓ), or germanium oxide (GeOx). HK gate dielectric layers 127 can include a high-k dielectric material, such as hafnium oxide (HfO₂), titanium oxide (TiO₂), hafnium zirconium oxide (HfZrO), tantalum oxide (Ta₂O₃), hafnium silicate (HfSiO4), zirconium oxide (ZrO₂), and zirconium silicate (ZrSiO₂). In some embodiments, WFM layer 128 can include titanium aluminum (TiAl), titanium aluminum carbide (TiAlC), tantalum aluminum (TaAl), tantalum aluminum carbide (TaAlC), Al-doped Ti, Al-doped TiN, Al-doped Ta, Al-doped TaN, other suitable Al-based materials, or a combination thereof for NFETs 102A and 102B. In some embodiments, WFM layers 128 can include substantially Al-free (e.g., with no Al) Ti-based or Ta-based nitrides or alloys, such as titanium nitride (TiN), titanium silicon nitride (TiSiN), titanium gold (Ti—Au) alloy, titanium copper (Ti—Cu) alloy, tantalum nitride (TaN), tantalum silicon nitride (TaSiN), tantalum gold (Ta—Au) alloy, tantalum copper (Ta—Cu), and a combination thereof for PFETs 102A and 102B. In some embodiments, gate metal fill layers 130 can include a suitable conductive material, such as tungsten (W), Ti, silver (Ag), ruthenium (Ru), molybdenum (Mo), copper (Cu), cobalt (Co), Al, iridium (Ir), nickel (Ni), metal alloys, and a combination thereof.

Referring to FIGS. 1A, 1B, and 1D, in some embodiments, poly-cut structure 132 can be disposed between FET 102A and FET 102B. In some embodiments, poly-cut structure 132 can electrically isolate gate structures 120 disposed on fin bases 106A and 106B from each other. In some embodiments, poly-cut structure 132 can include a dielectric material, such as SiN, SiO₂, SiOCN, SiOC, SiON, and other suitable dielectric materials. In some embodiments, the dielectric material of poly-cut structure 132 can be different from the dielectric material of ILD layers 112.

In some embodiments, poly-cut structure 132 can be disposed directly on STI region 116 between fin bases 106A and 106B. In some embodiments, poly-cut structure 132 can be in direct contact with HK gate dielectric layers 127 of gate structures 120. In some embodiments, a bottom surface of poly-cut structure 132 can be substantially coplanar with top surfaces of fin bases 106A and 106B under nanostructured channel regions 122. In some embodiments, poly-cut structure 132 can have a T-shaped cross-sectional profile. In some embodiments, poly-cut structure 132 can include a first portion 132A extending vertically between the nanostructured channel regions on fin bases 106A and 106B and a second portion 132B extending horizontally over nanostructured channel regions on fin bases 106A and 106B. In some embodiments, second portion 132B extends horizontally perpendicular to first portion 132A and parallel to fin bases 106A and 106B.

Referring to FIG. 1B, in some embodiments, protective oxide layers 134 can be disposed between nanostructured channel regions 122 and poly-cut structure 132. In some embodiments, protective oxide layers 134 can be disposed directly on sidewalls of nanostructured channel regions 122 and poly-cut structure 132 facing each other. In some embodiments, protective oxide layers 134 can have thicknesses along a Z-axis greater than thicknesses of nanostructured channel regions 122 along a Z-axis. In some embodiments, top and bottom surfaces of protective oxide layers 134 can be in direct contact with HK gate dielectric layers 127. In some embodiments, sidewalls of protective oxide layers 134 can be in direct contact with IL layers 126. In some embodiments, protective oxide layers 134 can include an oxide dielectric material, such as SiO₂, SION, SIOCN, SiOC, and other suitable oxide dielectric material. In some embodiments, protective oxide layer 134 can be deposited using atomic layer deposition.

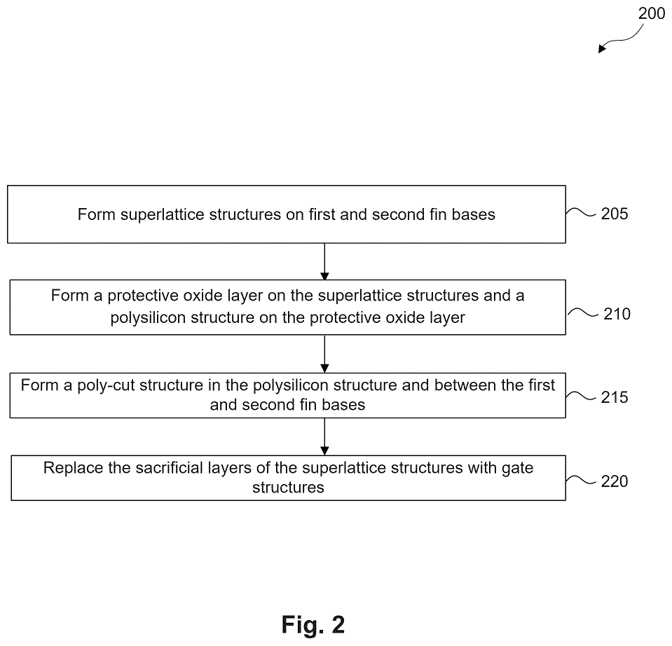

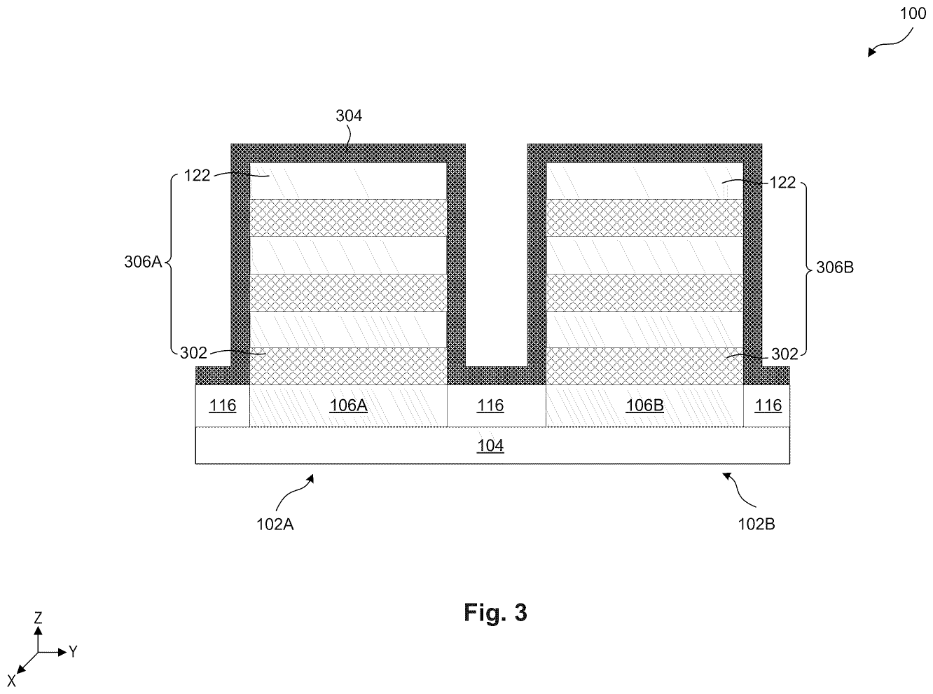

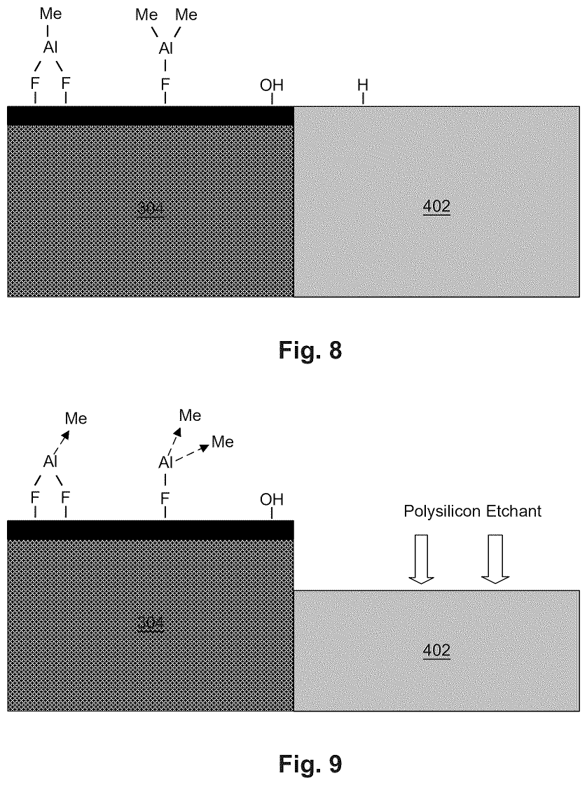

FIG. 2 is a flow diagram of an example method 200 for fabricating semiconductor device 100 as described above with reference to FIGS. 1A-1D. For illustrative purposes, the operations illustrated in FIG. 2 will be described with reference to the example fabrication process for fabricating semiconductor device 100 as illustrated in FIGS. 3-14. FIGS. 3-7 and 10-14 illustrate cross-sectional views of semiconductor device 100 along line A-A of FIG. 1A at various stages of fabrication, according to some embodiments. FIGS. 8 and 9 illustrate process mechanisms of fabrication processes of semiconductor device 100, according to some embodiments. Operations of method 200 can be performed in a different order or not performed depending on specific applications. It should be noted that method 200 may not produce complete semiconductor device 100. Accordingly, it is understood that additional processes can be provided before, during, and after method 200, and that some other processes may only be briefly described herein. The discussion of elements in FIGS. 1A-1D and 3-14 with the same annotations applies to each other, unless mentioned otherwise.

Referring to FIG. 2, in operation 205, superlattice structures are formed on first and second fin bases. For example, as described with reference to FIG. 3, superlattice structures 306A and 306B (also referred to as “nanosheet stacks 306A and 306B”) are formed on fin bases 106A and 106B, respectively. Superlattice structure 306A can include nanostructured layers 122 and 302 arranged in an alternating configuration. Similarly, superlattice structure 306B can include nanostructured layers 122 and 302 arranged in an alternating configuration. Nanostructured layers 302 are also referred to as “sacrificial layers 302.” In some embodiments, nanostructured layers 122 can include Si and nanostructured layers 302 can include SiGe. In some embodiments, each of nanostructured layers 122 and 302 can have a thickness of about 3 nm to about 15 nm along a Z-axis.

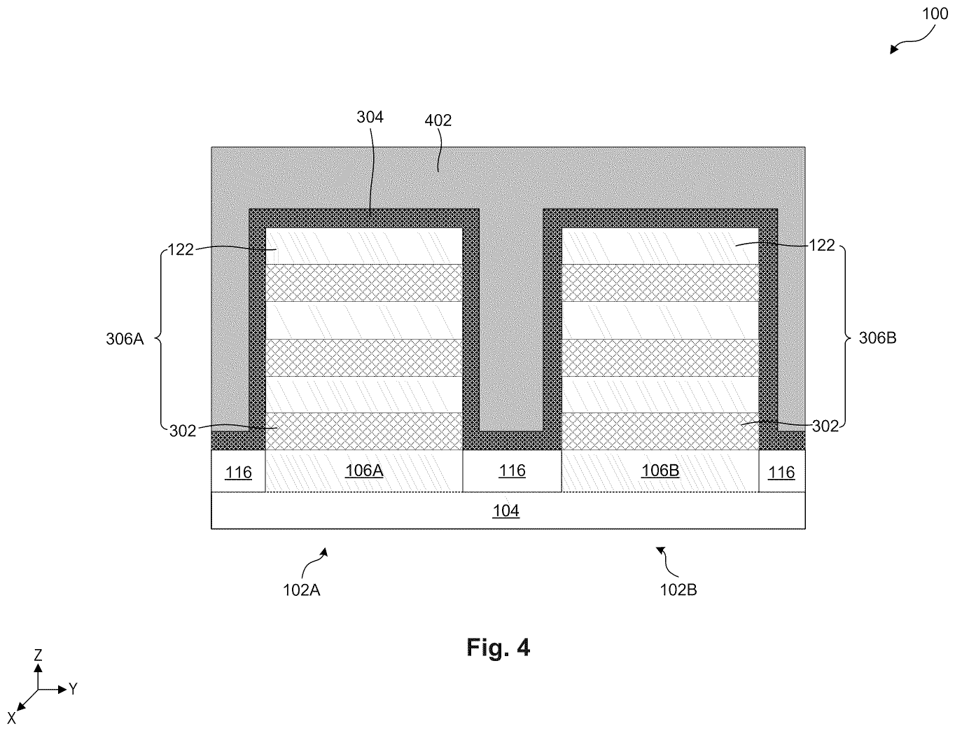

Referring to FIG. 2, in operation 210, a protective oxide layer is formed on the superlattice structures and a polysilicon structure is formed on the protective oxide layer. For example, as described with reference to FIGS. 3 and 4, a protective oxide layer 304 can be formed on superlattice structures 306A and 306B and polysilicon structure 402 can be formed on superlattice structures 306A and 306B. In some embodiments, forming protective oxide layer 304 can include depositing a dielectric layer of SiO₂, SION, SiOCN, SiOC, or other suitable oxide dielectric materials substantially conformally on superlattice structures 306A and 306B and STI regions 116. Protective oxide layer 304 can be deposited to protect nanostructured layers 122 during a subsequent poly-cut process. In some embodiments, protective oxide layer 304 can be about 2 nm to about 3 nm thick. Protective oxide layer 304 and polysilicon layer 402 can wrap around the superlattice structures 306A and 306B. In some embodiments, forming polysilicon structure 402 can include depositing a polysilicon layer on protective oxide layer 304, as shown in FIG. 4. In some embodiments, during subsequent processing, polysilicon structure 402 and sacrificial layers 302 can be replaced with gate structures 120 in a gate replacement process

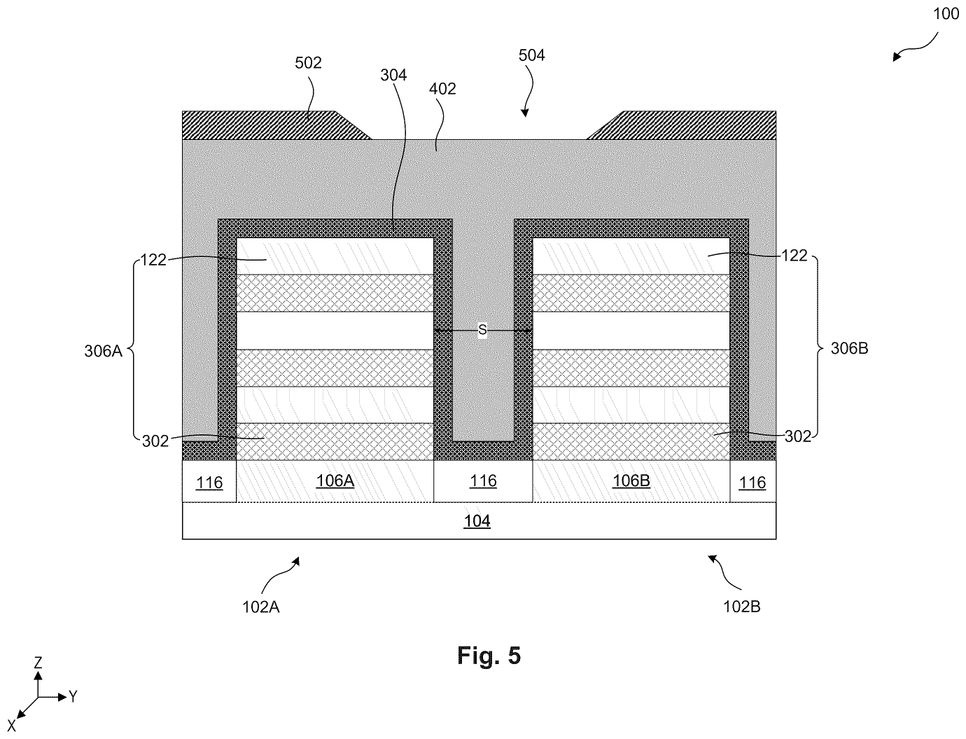

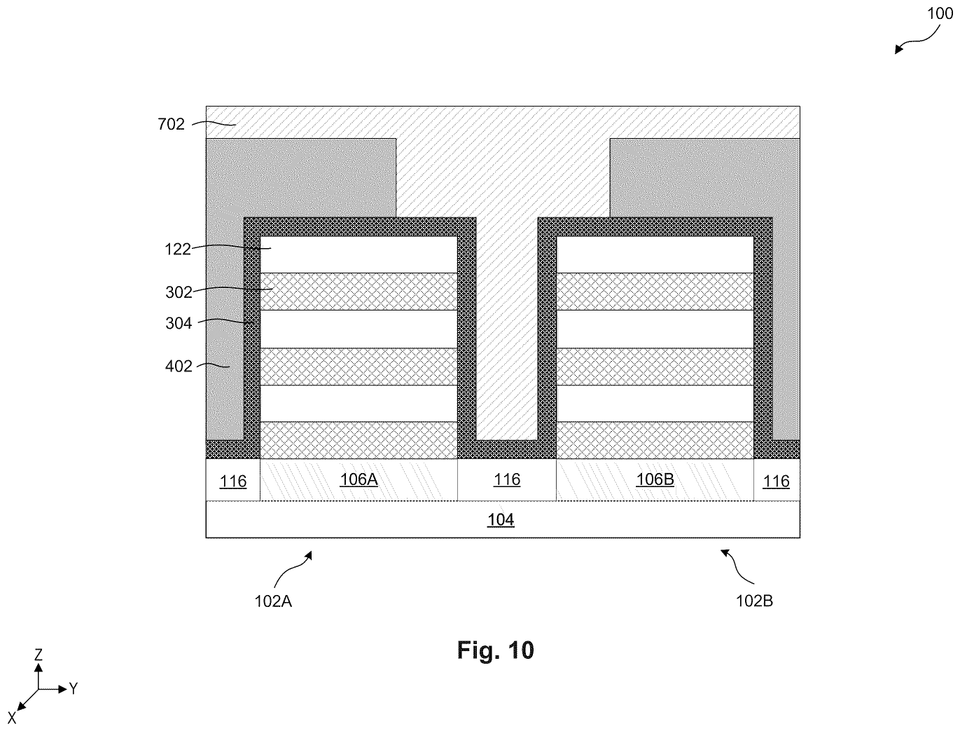

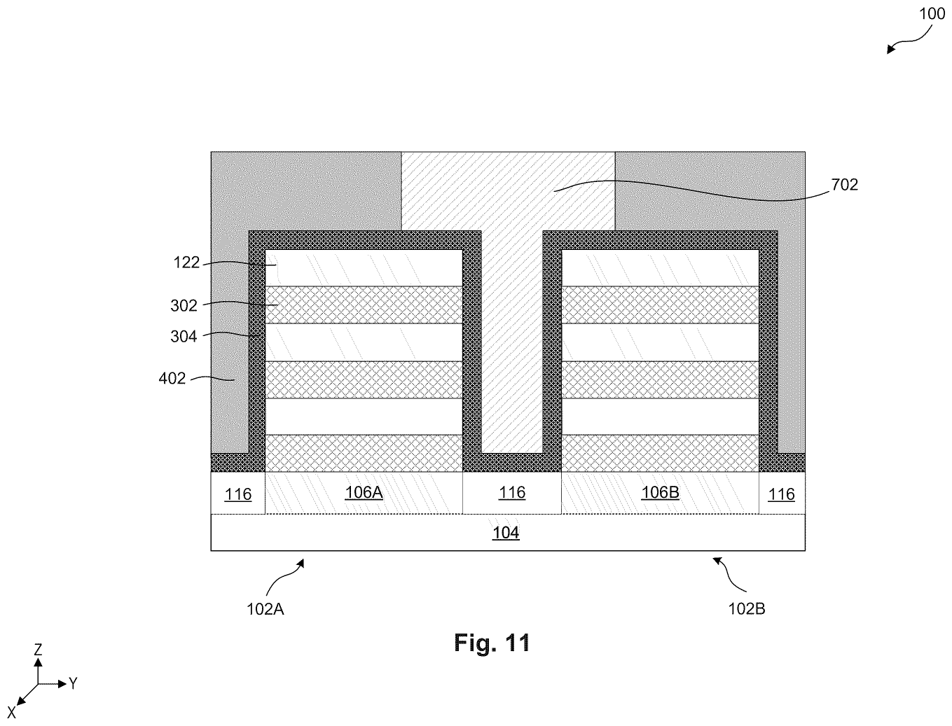

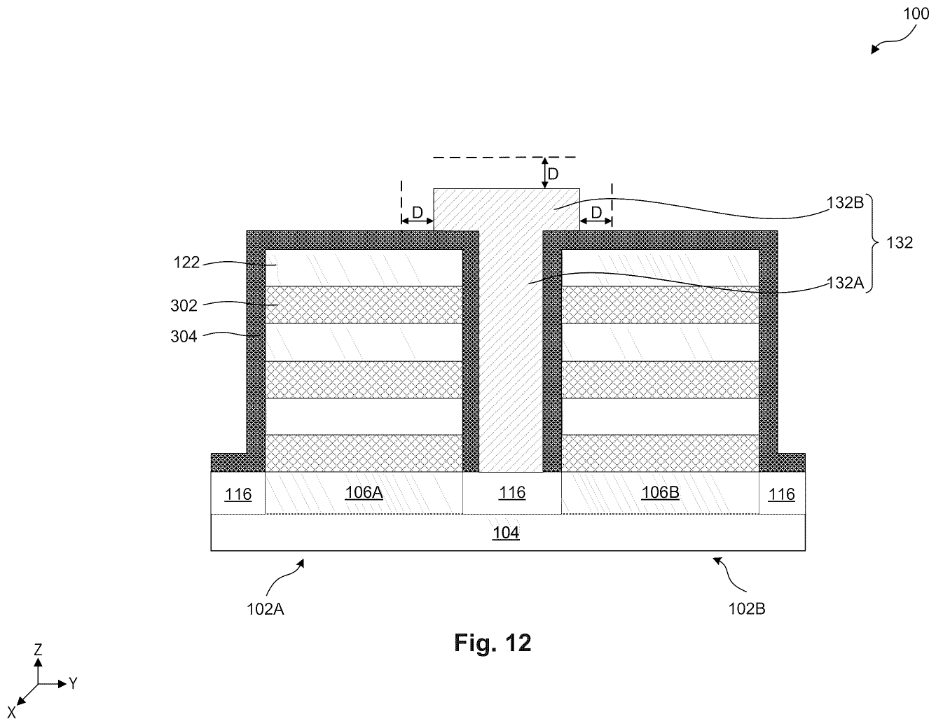

Referring to FIG. 2, in operation 215, a poly-cut structure is formed in the polysilicon structure and between the first and second fin bases. For example, as described with reference to FIGS. 5-11, poly-cut structure 132 can be formed in polysilicon structure 402 and between fin bases 106A and 106B. In some embodiments, forming poly-cut structure 132 can include sequential operations of (i) forming poly-cut opening 604A and 604B (also referred to as “isolation openings 604A and 604B” or “isolation trenches 604A and 604B”), as described with reference to FIGS. 5-9, (ii) depositing a dielectric layer 702 in poly-cut openings 604A and 604B, as shown in FIG. 10, (iii) performing a chemical mechanical polishing (CMP) process to coplanarize top surfaces of dielectric layer 702 with top surfaces of polysilicon structure 402, as shown in FIG. 11, and (iv) performing a trimming process on dielectric layer 702 of FIG. 11 to form poly-cut structure 132 as shown in FIG. 12.

In some embodiments, forming poly-cut opening 604A can include depositing and patterning a hard mask 502 on polysilicon structure 402 to define an opening 504 for the subsequent poly-cut process. As spacing S between fin bases 106A and 106B is less 25 nm along a Y-axis, opening 504 is formed with a width along a Y-axis greater than spacing S, and as a result, poly-cut opening 604A above superlattice structures 306A and 306B is formed with a width W greater than spacing S in subsequent poly-cut process.

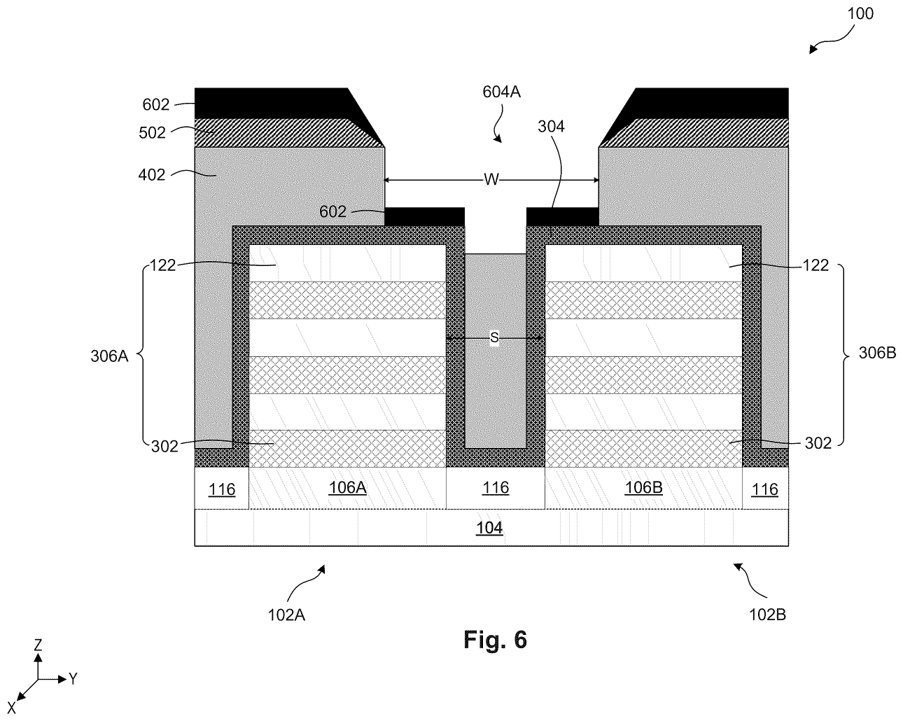

In some embodiments, forming poly-cut opening 604A can further include performing a poly-cut process through opening 504. The poly-cut process can include an etch process to remove portions of polysilicon structure 402 exposed through opening 504. As opening 504 is greater than spacing S, portions of top surface of protective oxide layer 304 can be exposed during the poly-cut process, as shown in FIG. 6. If the exposed portions of protective oxide layer 304 are not protected during the poly-cut process, the uppermost nanostructured layer 122 can be damaged during the poly-cut process. To prevent such damage, the poly-cut process can include forming protective metal oxide layers 602 in addition to etching portions of polysilicon structure 402 through opening 504.

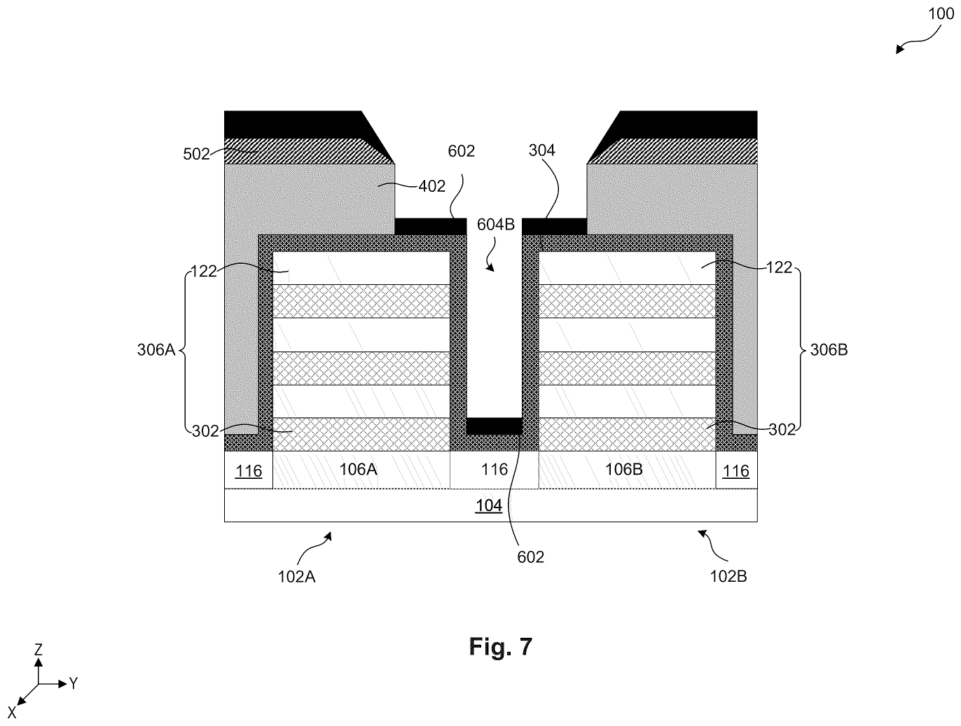

Since the poly-cut process is an isotropic etch process, horizontal surfaces are more susceptible to ion damage than sidewall surfaces primarily because of the high energy with which the ions impinge on horizontal surfaces. For example, the horizontal surfaces of protective oxide layer 304 underlying opening 504 can be more susceptible to ion damage during the poly-cut process than sidewall surfaces of protective oxide layer 304 underlying opening 504. Therefore, the horizontal surfaces of protective oxide layer 304 underlying opening 504 can be protected by protective metal oxide layers 602 during the poly-cut process. In some embodiments, protective metal oxide layers 602 can be formed on horizontal surfaces of protective oxide layer 304 on superlattice structures 306A and 306B exposed during the poly-cut process on polysilicon structure 402 to form poly-cut opening 604A, as shown in FIG. 6. In some embodiments, protective metal oxide layer 602 can be formed on horizontal surfaces of protective oxide layer 304 on STI regions 116 exposed during the poly-cut process on polysilicon structure 402 to form poly-cut opening 604B, as shown in FIG. 7.

In some embodiments, polysilicon structure 402 can be etched through opening 504 using the poly-cut etch process that is (i) selective to polysilicon structure 402 over protective oxide layer 304, and (ii) capable of protecting protective oxide layer 304 and the uppermost nanostructured layer 122 underneath protective oxide layer 304. To achieve a combination of requirements (i) and (ii), the poly-cut etch process can be a dry etch process that uses a polysilicon etchant having (i) fluorine, chlorine, or bromine to etch polysilicon structure 402, and (ii) dimethylaluminum chloride (DMAC) and hydrogen fluoride (HF) to form protective metal oxide layers 602. The protective metal oxide layer 602 is deposited using an ion-enhanced deposition process, where the reactant ions (HF ions and DMAC ions) are provided with energy to promote a directional deposition process. Referring to FIGS. 6 and 7, during deposition of the protective metal oxide layer 602, the DMAC ions and HF ions are provided vertical directionality to promote deposition of the protective metal oxide layer 602 on horizontal surfaces, such as (a) a top surface of hard mask layer 502, (b) a top surface of exposed oxide layer 304, and (c) on protective oxide layer 304 surface at the bottom of poly-cut opening 604B. The vertical directionality of DMAC and HF ions does not favor formation of protective metal oxide layer 602 on sidewalls of polysilicon layer 402 and sidewalls of poly-cut openings 604A and 604B. As illustrated in FIGS. 8 and 9, HF reacts with DMAC to form trimethylaluminum fluoride (Al(CH₃)F₂) that can selectively adhere to the surface of protective oxide layer 304 due to the presence of —OH dangling bonds. The methyl groups can be removed as non-volatile by-product leaving behind aluminum fluoride (AlF₃) on the surface of protective oxide layer 304. The AlF₃ can selectively react with the oxygen from protective oxide layer 304 to form aluminum oxide (Al₂O₃) based protective metal oxide layers 602. In some embodiments, Al₂O₃ based protective metal oxide layers 602 can include traces of AlF₃. The surface of polysilicon structure 402 has —H dangling bonds, which does not assist with polysilicon surface incubation with Al(CH₃)F₂. Therefore, protective metal oxide layer 602 does not form on the surface of polysilicon structure 402. Therefore, protective metal oxide layer 602 does not form on the exposed sidewalls of polysilicon structure 402 of FIGS. 6 and 7. Furthermore, the non-volatile by-product having the methyl groups can adhere to the sidewalls of protective oxide layer 304 thereby retarding the formation of protective metal oxide layer 602 on the sidewalls. In some embodiments, protective metal oxide layer 602 can have a thickness of about 1 nm to about 3 nm. In some embodiments, instead of DMAC and HF, dimethyltitanium chloride and HF can be used to form a titanium oxide (TiO₂) based protective metal oxide layer 602 with traces of titanium fluoride (TiF).

The poly-cut process can be performed in an ICP (Inductively Coupled Plasma), CCP (Capacitively Coupled Plasma), or ECR (Electron Cyclotron Resonance) etching apparatus. To form the AlO-based protective metal oxide layer 602, an aluminum containing gas, such as DMAC or aluminum chloride (AlCl₃) and HF can be introduced into the etching apparatus along with the polysilicon etchant gases. Co-reactant gases, for example H₂, COₓ, or CHₓ can be simultaneously flowed into the etching apparatus. The poly-cut process can be performed at a temperature of about 50° C. to about 350° C., and a process pressure of about 1 mtorr to about 1 torr. The poly-cut process can use a source power between about 50 to about 1200 W, and a source power frequency equal to or greater than about 13.56 MHz. To make the etch process isotropic, the poly-cut process can use a bias power of about 1 V to about 1200V and a bias power frequency lower than about 13.56 MHZ.

In some embodiments, the formation of openings 604A and 604B can be followed by the removal of protective metal oxide layers 602. Protective oxide layer 602 containing aluminum polymer can be removed using a Standard Clean-1 (SC-1) solution. The SC-1 solution can include a mixture of ammonia hydroxide (NH₄OH), hydrogen peroxide (H₂O₂), and water. The SC1 solution can selectively remove protective metal oxide layer 602 over the protective oxide 304.

In some embodiments, the removal of protective oxide layer 602 can be followed by the deposition of dielectric layer 702, as shown in FIG. 11, which can be followed by the CMP process to form dielectric layer 702 shown in FIG. 11. In some embodiments, depositing dielectric layer 702 in poly-cut openings 604A and 604B can include depositing dielectric layer 702 using a chemical vapor deposition process. In some embodiments, after the CMP process, remaining portions of polysilicon structure 402 surrounding protective oxide layer 304 and poly-cut structure 132 can be removed as shown in FIG. 12.

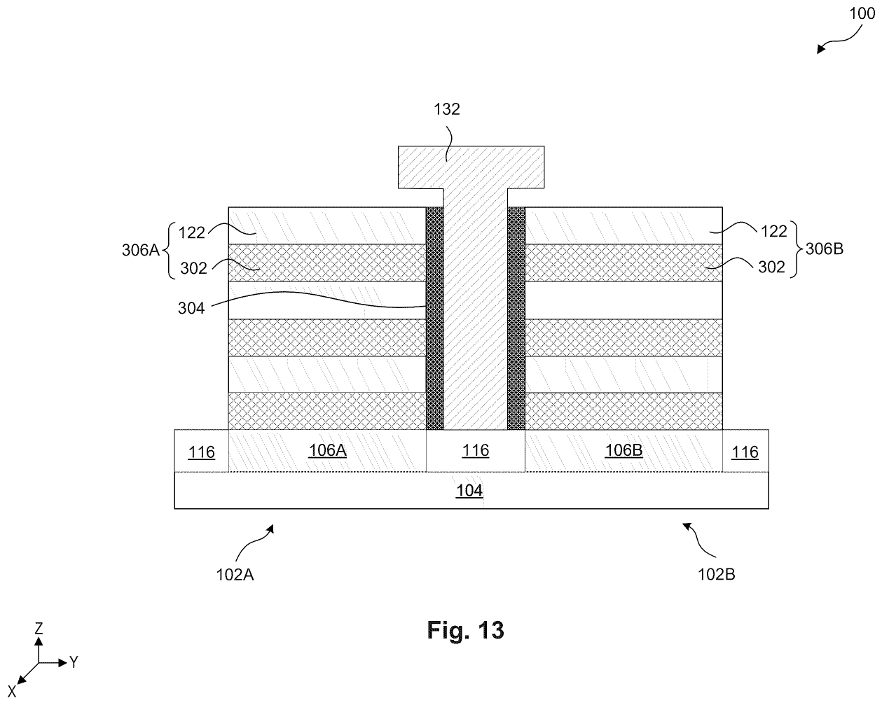

In some embodiments, following the removal of polysilicon structure 402, a top portion and side portions of dielectric layer 702 of FIG. 11 can be trimmed to form poly-cut structure 132 shown in FIG. 12. As shown in FIG. 12, the top portion and side portions of dielectric layer 702 can be trimmed by a thickness D to form poly-cut structure 132. The trimming process can involve an isotropic etching process, wherein the etchant selectively removes dielectric layer 702 over protective oxide layer 304. The trimming operation can expose larger areas of protective oxide layer 304, which can lead to easier removal of protective oxide layer 304 in subsequent steps. It can further assist uniform deposition of HK dielectric layer 127, WFM layer 128, and gate metal fill layer 130 in recesses between poly-cut structure 132 and the uppermost nanostructured layer 122, After the trimming process, portions of protective oxide layer 304 from top surfaces of superlattice structures 306A and 306B and from sidewalls of superlattice structures 306A and 306B that are not facing poly-cut structure 132 can be removed to expose superlattice structures 306A and 306B, as shown in FIG. 13.

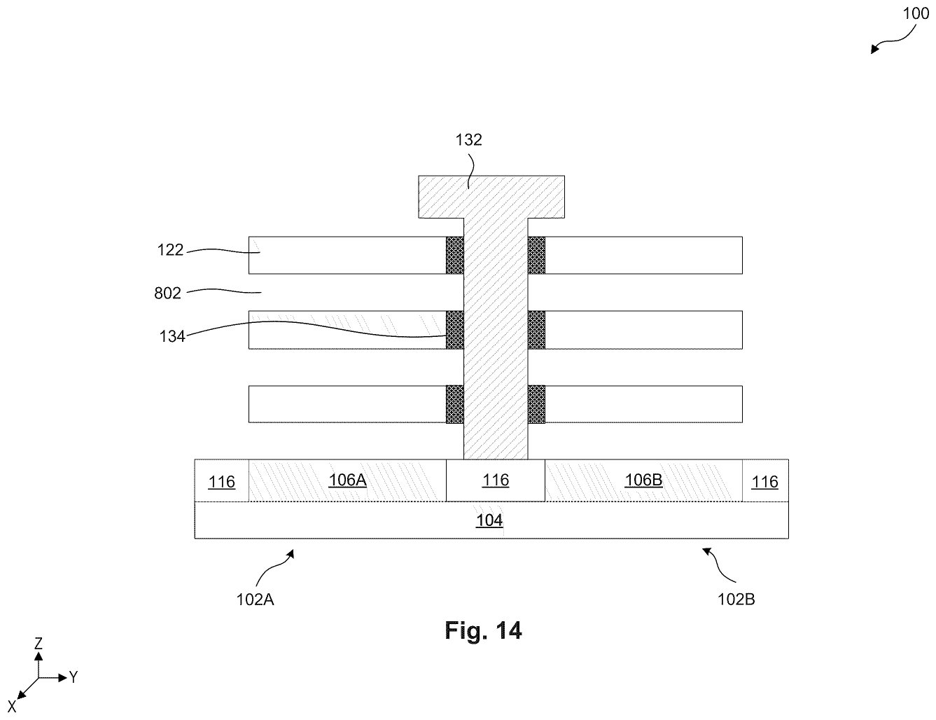

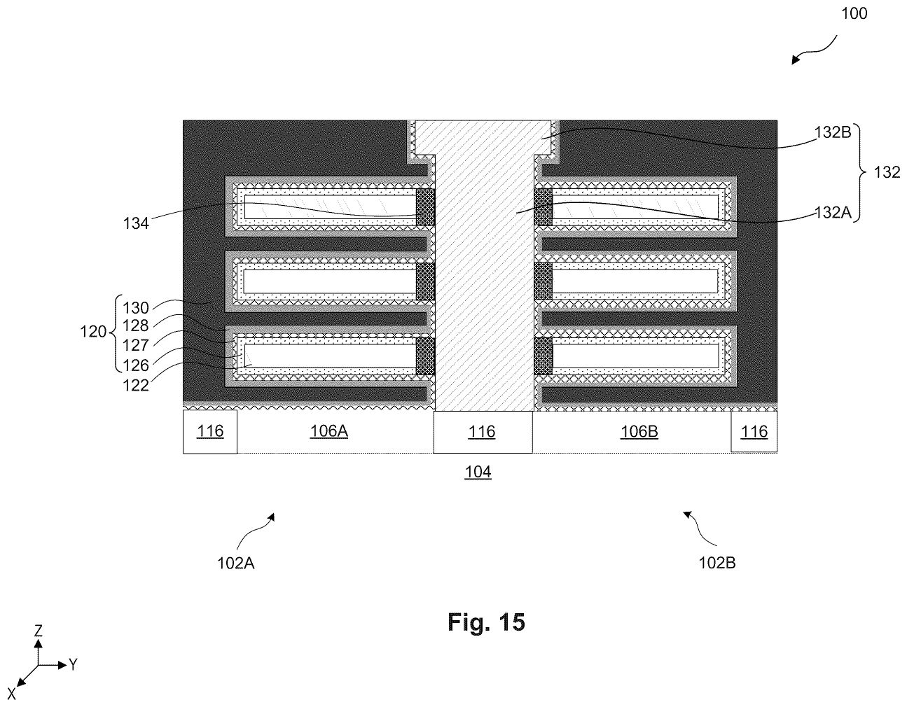

Referring to FIG. 2, in operation 220, the sacrificial layers of the superlattice structures are replaced with gate structures. For example, as described with reference to FIGS. 14-15, sacrificial layers 302 are replaced with gate structures 120. The formation of gate structures 120 can include sequential operations of (i) etching sacrificial layers 302 of superlattice structures 306A and 306B, as shown in FIG. 14, (ii) etching portions of protective layer oxide 304 on sidewalls of poly-cut structure 132 that are exposed after the etching of sacrificial layers 302, as shown in FIG. 14, (iii) forming IL layers 126 on exposed surfaces of nanostructured layers 122, as shown in FIG. 15, (iv) depositing HK dielectric layers 127 on IL layers 126, as shown in FIG. 15, (v) depositing WFM layers 128 on HK dielectric layers 127, as shown in FIG. 15, (vi) depositing gate metal fill layers 130 on WFM layers 128, as shown in FIG. 15, and (vii) performing a CMP process to coplanarize top surfaces of HK gate dielectric layers 127, WFM layers 128, gate metal fill layers 130 and poly-cut structure 132 with each other.

The present disclosure provides a semiconductor device (e.g., semiconductor device 100) and an example method (e.g., method 200) for addressing challenges with forming poly-cut structures (e.g., poly-cut structures 132) in a semiconductor device. The semiconductor device can include superlattice structures (e.g., superlattice structures 306A and 306B) with nanostructured layers (e.g., nanostructured layers 122 and 302) on fin bases (e.g., fin bases 106A and 106B). The nanostructured layers can include channel regions. As spacing between adjacent superlattice structures decreases with advance in semiconductor technology, defining and forming poly-cut structures between adjacent superlattice structures becomes challenging. Defining and forming the poly-cut structures in a spacing less than about 25 nm between adjacent superlattice structures is challenging because the extreme ultra-violet (EUV) lithography and etch processes used in the fabrication of the semiconductor device are unable to accommodate process variations. Furthermore, when the spacing is less than about 25 nm, the poly-cut opening (also referred to as an “isolation opening”) lands on top of the nanostructured layer of the superlattice structure, which can induce damage to the nanostructured layers during the formation of the poly-cut structures. The process of forming the poly-cut structures can be referred to as a “poly-cut process”.

To address these challenges, the present disclosure provides a method to protect the nanostructured layer of the superlattice structures using a protective oxide layer (e.g., protective oxide layer 134). The protective oxide layer can be formed on the superlattice structures prior to forming the poly-cut structures. Since, the protective oxide layer is thin, the poly-cut process can deteriorate the protective oxide layer, which can induce damage on uppermost nanostructured layers of the superlattice structures. The damage can be attributed to a high ion energy of ions of a poly-cut etchant of the poly-cut process, which can penetrate the thin protective oxide layer. Since the poly-cut etch process is an isotropic etch process, flat surfaces are more susceptible to ion damage than sidewall surfaces primarily because of the high energy with which the ions impinge on the flat surfaces. The damage can cause round top corners of the uppermost nanostructured layers of the superlattice structures. A difference in dimensions of the uppermost nanostructured layer compared to other nanostructured layers in the superlattice structure can cause the uppermost nanostructured layer to have current transfer characteristics different from the current transfer characteristics of the other nanostructured layers in the superlattice structure.

The present disclosure further provides an example method for protecting the protective oxide layer to prevent damage to the nanostructured layers (e.g., the uppermost nanostructured layer) of the superlattice structures. In some embodiments, the example method includes selectively depositing a protective metal oxide layer (e.g., protective metal oxide layer 602) on surfaces of the protective oxide layer exposed during the poly-cut etch process. The protective metal oxide layer can be selectively formed on the protective oxide layer surfaces on sacrificial polysilicon structures. The protective metal oxide layer formation can also be selective to surfaces parallel to horizontal surfaces (e.g., top and bottom surfaces of protective oxide layer) over vertical surfaces (e.g., sidewall surfaces of protective oxide layer). This protective metal oxide layer can be formed during the poly-cut process and can be selectively deposited on horizontal surfaces of the protective oxide layer that get exposed during the poly-cut etch process.

In some embodiments, a method includes forming a first superlattice structure and a second superlattice structure on a substrate, forming a dielectric oxide layer on the first superlattice structure and the second superlattice structure, forming a polysilicon layer on the dielectric oxide layer, forming a first isolation opening above the first superlattice structure and the second superlattice structure, forming a second isolation opening between the first superlattice structure and the second superlattice structure, and depositing a dielectric layer in the first and second isolation openings to form an isolation structure. Forming the first isolation opening includes forming a first metal oxide layer on a first portion of the dielectric oxide exposed during forming of the first isolation opening. Forming the second isolation opening includes forming a second metal oxide layer on a second portion of the dielectric oxide layer exposed during forming of the second isolation opening.

In some embodiments, a method includes forming a first superlattice structure and a second superlattice structure on a substrate, forming a first protective layer surrounding the first superlattice structure and the second superlattice structure, forming a polysilicon structure on the first protective layer, forming a poly-cut opening between the first superlattice structure and the second superlattice structure, depositing a dielectric layer in the poly-cut opening, forming gate openings in the first superlattice structure and the second superlattice structure, removing portions of the first protective layer in the gate openings, and forming gate structures in the gate openings. Forming the poly-cut opening includes forming a second protective layer on a portion of the first protective layer exposed during forming of the poly-cut opening.

In some embodiments, a semiconductor device includes a substrate, a first nanostructured channel region disposed on the substrate, a first gate structure surrounding the first nanostructured channel region, a second nanostructured channel region disposed on the substrate, a second gate structure surrounding the second nanostructured channel region, an isolation structure disposed between the first and second nanostructured channel regions, a first protective oxide layer disposed between the first nanostructured channel region and the isolation structure, and a second protective oxide layer disposed between the second nanostructured channel region and the isolation structure.

The foregoing disclosure outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first superlattice structure and a second superlattice structure on a substrate;
forming a dielectric oxide layer on the first superlattice structure and the second superlattice structure;
forming a polysilicon layer on the dielectric oxide layer;
forming, above the first superlattice structure and the second superlattice structure, a first isolation opening comprises forming a first metal oxide layer on a first portion of the dielectric oxide exposed during forming of the first isolation opening;
forming, between the first superlattice structure and the second superlattice structure, a second isolation opening comprises forming a second metal oxide layer on a second portion of the dielectric oxide layer exposed during forming of the second isolation opening; and
depositing a dielectric layer in the first and second isolation openings to form an isolation structure.

2. The method of claim 1, wherein forming the first isolation opening further comprises etching a first portion of the polysilicon layer above the first superlattice structure and the second superlattice structure.

3. The method of claim 1, wherein forming the second isolation opening further comprises etching a second portion of the polysilicon layer between the first superlattice structure and the second superlattice structure.

4. The method of claim 1, wherein forming the second isolation opening comprises exposing sidewalls of the dielectric oxide layer between the first superlattice structure and the second superlattice structure.

5. The method of claim 1, wherein forming the first metal oxide layer comprises forming an aluminum oxide layer using dimethyl aluminum chloride and hydrogen fluoride.

6. The method of claim 1, wherein the first portion of the dielectric oxide is disposed on a top surface of the first superlattice structure.

7. The method of claim 1, wherein the second portion of the dielectric oxide is disposed on a shallow trench isolation region between the first superlattice structure and the second superlattice structure.

8. The method of claim 1, further comprising removing the first and second metal oxide layers prior to depositing the dielectric layer.

9. The method of claim 1, wherein depositing a high-k dielectric layer on sidewalls of the isolation structure.

10. The method of claim 1, further comprising performing a chemically mechanical polishing process to coplanarize top surfaces of the dielectric layer and the polysilicon layer with each other.

11. A method, comprising:
forming a first superlattice structure and a second superlattice structure on a substrate;
forming a first protective layer surrounding the first superlattice structure and the second superlattice structure;
forming a polysilicon structure on the first protective layer;
forming a poly-cut opening between the first superlattice structure and the second superlattice structure comprising forming a second protective layer on a portion of the first protective layer exposed during forming of the poly-cut opening;
depositing a dielectric layer in the poly-cut opening;
forming gate openings in the first superlattice structure and the second superlattice structure;
removing portions of the first protective layer in the gate openings; and
forming gate structures in the gate openings.

12. The method of claim 11, wherein forming the second protective layer comprises forming a layer comprising aluminum oxide with traces of aluminum fluoride.

13. The method of claim 11, wherein the portion of the first protective layer is disposed on top surfaces of the first superlattice structure and the second superlattice structure.

14. The method of claim 11, wherein the portion of the first protective layer is disposed on top surfaces of an isolation region.

15. The method of claim 11, wherein forming the poly-cut opening comprises isotropically etching the polysilicon structure.

16. The method of claim 11, wherein forming the poly-cut opening comprises etching the polysilicon structure at a temperature of about 50° C. to about 350° C.

17. A semiconductor device, comprising:
a substrate;
a first nanostructured channel region disposed on the substrate;
a first gate structure surrounding the first nanostructured channel region;
a second nanostructured channel region disposed on the substrate;
a second gate structure surrounding the second nanostructured channel region;
an isolation structure disposed between the first and second nanostructured channel regions;
a first protective oxide layer disposed between the first nanostructured channel region and the isolation structure; and
a second protective oxide layer disposed between the second nanostructured channel region and the isolation structure.

18. The semiconductor device of claim 17, wherein the first and second protective oxide layers comprise aluminum oxide.

19. The semiconductor device of claim 17, wherein the isolation structure comprises a T-shaped cross-sectional profile.

20. The semiconductor device of claim 17, wherein the first protective oxide layer is in contact with a high-k gate dielectric layer of the first gate structure.
